(19) United States
(12) Patent Application Publication
(10) Pub. No.: US 2024/0099165 A1
(43) Pub. Date: Mar. 21, 2024

(54) SEMICONDUCTOR DEVICE

(71) Applicants: KOREA ADVANCED INSTITUTE OF SCIENCE AND TECHINOLOGY, Daejeon (KR); RESEARCH & BUSINESS FOUNDATION SUNGKYUNKWAN UNIVERSITY, Suwon-si, (KR)

(72) Inventors: Heejun YANG, Daeieon (KR); Eunji Hwang, Daejeon (KR); Yonas Assefa Eshete, Suwon-si (KR)

(73) Assignees: KOREA ADVANCED INSTITUTE OF SCIENCE AND TECHINOLOGY, Daejeon (KR); RESEARCH & BUSINESS FOUNDATION SUNGKYUNKWAN UNIVERSITY, Suwon-si (KR)

(21) Appl. No.: 18/154,959

(22) Filed: Jan. 16, 2023

(30) Foreign Application Priority Data
Sep. 16, 2022 (KR) 10-2022-0117116

(51) Int. Cl. H10N 70/20; H10N 70/00

(52) U.S. Cl. CPC H10N 70/253; H10N 70/235; H10N 70/8828

(57) ABSTRACT

Provided is a semiconductor device. The semiconductor device includes a phase change material layer on a substrate, a gate electrode disposed on the phase change material layer and inducing accumulation of charges in the phase change material layer, and a pair of source/drain electrodes spaced apart from each other with the gate electrode therebetween on the phase change material layer. The phase change material layer includes a phase change region having a crystal structure that changes due to the accumulation of the charges as a voltage is applied to the gate electrode.

### CROSS-REFERENCE TO RELATED APPLICATIONS

This U.S. non-provisional patent application claims priority under 35 U.S.C. § 119 of Korean Patent Application No. 10-2022-0117116, filed on Sep. 16, 2022, the entire contents of which are hereby incorporated by reference.

### BACKGROUND

The present disclosure herein relates to a semiconductor device, and more particularly, to a semiconductor device including a phase change material layer.

With the development of modern industry, semiconductor devices are more highly integrated. In particular, in the fields of artificial intelligence (AI) and machine learning, semiconductor devices capable of in-memory computing are required, and, to this end, it is necessary to develop highly integrated semiconductor devices capable of high-speed data processing with low power consumption. To meet these requirements, researches have been continuously carried out to develop semiconductor devices using a phase change such as Mott transition, amorphous-crystalline transition, or the like. However, additional research and development is required for industrially commercializing phase change semiconductor devices.

### SUMMARY

The present disclosure provides a semiconductor device capable of performing both data storage and operation.

The present disclosure also provides a semiconductor device with improved electrical characteristics.

The purposes of the present disclosure are not limited to the above-mentioned purposes, and other purposes not mentioned would be clearly understood by those skilled in the art from the disclosure below.

An embodiment of the inventive concept provides a semiconductor device including a phase change material layer on a substrate, a gate electrode disposed on the phase change material layer and inducing accumulation of charges in the phase change material layer, and a pair of source/drain electrodes spaced apart from each other with the gate electrode therebetween on the phase change material layer. In an embodiment, the phase change material layer may include a phase change region having a crystal structure that changes due to the accumulation of the charges as a voltage is applied to the gate electrode may be.

In an embodiment of the inventive concept, a semiconductor device includes a phase change material layer on a substrate, a gate electrode disposed on the phase change material layer, and a pair of source/drain electrodes spaced apart from each other with the gate electrode therebetween on the phase change material layer. In an embodiment, the phase change material layer may include a phase change region having a monoclinic structure and a base region having a hexagonal structure.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a semiconductor device according to embodiments of the inventive concept;

FIGS. 2A to 2C, which correspond to P1 of FIG. 1, are enlarged views illustrating a crystal structure change of a phase change material layer according to a cycle of voltage application to a gate electrode;

FIG. 3 is a graph illustrating lattice structure energy according to W content in Mo₁₋ₓWₓTe₂ for each crystal structure and electron density;

FIG. 4 is a graph illustrating a crystal structure according to electron density and W content in Mo₁₋ₓWₓTe₂;

FIG. 5 is a diagram schematically illustrating a semiconductor device according to Experimental Example 1;

FIG. 6 is a graph illustrating Raman spectra in a phase change material layer according to a voltage applied to the gate electrode in Experimental Example 1;

FIGS. 7A to 7C are graphs illustrating a hysteresis loop of a current according to a cycle of voltage application to the gate electrode of Experimental Example 1; and

FIG. 8 is a graph illustrating hysteresis loops of current according to the first and second voltages of Experimental Example 1.

### DETAILED DESCRIPTION

Hereinafter, a semiconductor device according to embodiments of the inventive concept and features thereof will be described in detail.

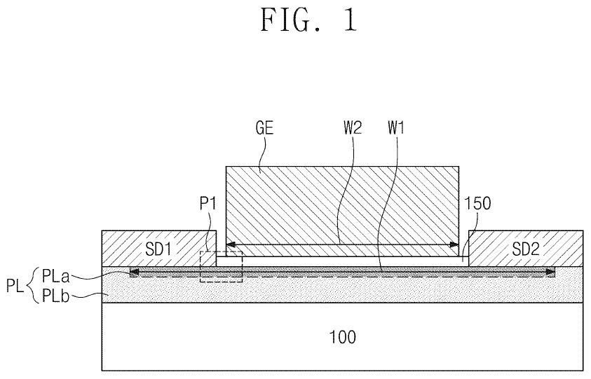

FIG. 1 is a cross-sectional view of a semiconductor device according to embodiments of the inventive concept.

Referring to FIG. 1, a semiconductor device may be provided. The semiconductor device may store data or perform data processing and operation. For example, the semiconductor device may be a memtransistor capable of performing both data storage and operation. However, the inventive concept is not limited thereto.

The semiconductor device may include a substrate 100, a phase change material layer PL, a gate electrode GE, and a pair of source/drain electrodes SD1 and SD2. The substrate 100 may include a semiconductor substrate, for example, silicon substrate, germanium substrate, or silicon-germanium substrate, or at least one of possible combinations thereof. The substrate 100 may be a multi-layer substrate. For example, the substrate 100 may include a semiconductor substrate and insulating substrate stacked sequentially. However, the inventive concept is not limited thereto.

The phase change material layer PL may be provided on the substrate 100. The phase change material layer PL may cover at least a portion of the substrate 100. The phase change material layer PL may function as a sort of a channel region in the semiconductor device according to the inventive concept. The phase change material layer PL may include a phase change region PLa and a base region PLb. The phase change region PLa may be one region of the phase change material layer PL, in which a crystal structure is changed by the gate electrode GE described below. The phase change region PLa may be adjacent to the gate electrode GE described below. The base region PLb may be another region of the phase change material layer PL other than the phase change region PLa. The phase change region PLa may be disposed between the base region PLb and the gate electrode GE described below. For example, an entire region of the phase change material layer PL may be the phase change region PLa. In other words, a crystal structure in the entire region of the phase change material layer PL may be changed by the gate electrode GE described below, and the base region PLb may not be provided. However, an embodiment of the inventive concept is not limited thereto.

The phase change material layer PL may include a material having a polymorphism characteristic. For example, the phase change material layer PL may include Mo₁₋ₓWₓTe₂ (where 0<x<1). An x value of the Mo₁₋ₓWₓTe₂ in the phase change material layer PL may be different for each region. The Mo₁₋ₓWₓTe₂ may have various crystal structures according to the x value (i.e., content ratio of Mo and W) and other external conditions. For example, the Mo₁₋ₓWₓTe₂ may have various crystal structures according to the x value and internal charge density. Therefore, a crystal structure of a channel region may be controlled by controlling the internal charge density and x value of the Mo₁₋ₓWₓTe₂, and characteristics of the channel region may be adjusted according to a change in the crystal structure. For example, the x value of the Mo₁₋ₓWₓTe₂ may be 0.05 to 0.15 in at least a partial region of the phase change material layer PL. Here, the crystal structure of the Mo₁₋ₓWₓTe₂ may change on the basis of electron density nₑ=1×10¹⁴ cm⁻² in the above region.

For example, the phase change material layer PL may have a hexagonal structure (2H structure). For another example, the phase change material layer PL may have a monoclinic structure (1T′ structure). For another example, the phase change material layer PL may have the 2H structure and 1T′ structure simultaneously. However, the inventive concept is not limited thereto. The crystal structure (e.g., crystal structure in the phase change region PLa) in the phase change material layer PL may be reversibly changed by the gate electrode GE described below.

The phase change material layer PL may be a material layer stacked in a plurality of layers on the substrate 100. The phase change region PLa may include an uppermost layer among the plurality of layers of the phase change material layer PL. In the present disclosure, the uppermost layer in the phase change material layer PL may represent a material layer which is closest to the gate electrode GE described below. A crystal structure of the uppermost layer among the plurality of layers may be changed to the 2H structure or 1T′ structure by the gate electrode GE described below. For example, a thickness of the phase change material layer PL in a stacking direction may be about 2 nm or less. Due to a thin thickness of the phase change material layer PL, energy consumption may be minimized during operation of the semiconductor device.

A gate insulating pattern 150 may be disposed between the phase change material layer PL and the gate electrode GE described below. The gate insulating pattern 150 may separate the phase change material layer PL and the gate electrode GE from each other. The gate insulating pattern 150 may insulate the phase change material layer PL and the gate electrode GE from each other.

The gate insulating pattern 150 may include, for example, silicon oxide, silicon oxynitride, or high-k material, or at least one of possible combinations thereof. The high-k material may include a high dielectric constant material having a higher dielectric constant than silicon oxide. For example, the high-k material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate, or at least one of possible combinations thereof. For another example, the gate insulating pattern 150 may include ion-gel. The ion-gel may include cations and anions, and have ionic conductivity.

The gate electrode GE may be disposed between the phase change material layer PL. The gate electrode GE may be disposed on the phase change region PLa of the phase change material layer PL. For example, as illustrated in FIG. 1, the phase change material layer PL may be provided in a plane form, and the gate electrode GE may be disposed on an upper surface of the phase change material layer PL. For another example, although not illustrated, a recess region may be included in the phase change material layer PL, and the gate electrode GE may be disposed on the phase change material layer PL within the recess region. For another example, although not illustrated, a portion of the phase change material layer PL may protrude upwards, and the gate electrode GE may be disposed on a front surface of a protruding region of the phase change material layer PL. However, this is merely an example, and the inventive concept is not limited thereto, and thus shapes of the gate electrode GE and the phase change material layer PL may be variously changed.

The gate electrode GE may change the crystal structure of the phase change material layer PL in at least a partial region of the phase change material layer PL. In more detail, accumulation of charges (e.g., electrons) may be induced in the phase change region PLa of the phase change material layer PL as a voltage is applied to the gate electrode GE, and the crystal structure of the phase change region PLa may change due to the accumulation of charges. Here, the gate electrode GE and the phase change material layer PL may be insulated from each other by the gate insulating pattern 150, and thus charges may be accumulated in the phase change region PLa without a current flow even if a voltage is applied to the gate electrode GE. For example, the crystal structure of the phase change region PLa may change to the 2H structure or 1T′ structure due to the accumulation of charges. In more detail, when a negative voltage that is at least a threshold voltage is applied into the gate electrode GE (i.e., when charges are accumulated to at least a certain degree in the phase change region PLa) when the phase change region PLa has the 2H structure, the crystal structure of the phase change region PLa may change to the 1T′ structure. Thereafter, the phase change region PLa may maintain the 1T′ structure even if the voltage is removed from the gate electrode GE (i.e., the voltage is 0 V). On the contrary, when a negative voltage that is lower than the threshold voltage is applied into the gate electrode GE when the phase change region PLa has the 1T′ structure, the crystal structure of the phase change region PLa may change to the 2H structure. Thereafter, the phase change region PLa may maintain the 2H structure even if the voltage is removed from the gate electrode GE.

While the crystal structure of the phase change region PLa changes due to the voltage of the gate electrode GE, a crystal structure of the base region PLb may be maintained. For example, the crystal structure of the base region PLb may be maintained as the 2H structure even if the voltage of the gate electrode GE changes. For another example, the crystal structure of the base region PLb may be maintained as the 1T′ structure even if the voltage of the gate electrode GE changes. Therefore, the phase change region PLa may have a crystal structure that is the same as or different from the crystal structure of the base region PLb according to a change in the voltage. For example, the phase change region PLa and the base region PLb may both have the 2H structure. For another example, the phase change region PLa may have the 1T′ structure, and the base region PLb may have the 2H structure.

When the crystal structure of the phase change region PLa is the 2H structure, a material of the phase change region PLa may have properties of a semiconductor. When the crystal structure of the phase change region PLa is the 1T′ structure, the material of the phase change region PLa may have high electric conductivity equivalent to that of metal. Therefore, electric conductivity of the phase change region PLa may be adjusted by controlling the voltage applied to the gate electrode GE.

A width W1 of the phase change region PLa may be larger than a width of the gate electrode GE. Here, the widths may be measured along a direction in which the pair of source/drain electrodes SD1 and SD2, described below, are space apart from each other.

The gate electrode GE may include, for example, doped semiconductor (e.g., doped silicon or the like), metal (e.g., tungsten, copper, aluminum, gold, chromium, or the like), conductive metal nitride (e.g., titanium nitride, tantalum nitride, or the like), or transition metal (e.g., titanium, tantalum, or the like), or at least one of possible combinations thereof.

The pair of source/drain electrodes SD1 and SD2 may be disposed on the phase material layer PL. The pair of source/drain electrodes SD1 and SD2 may include a first source/drain electrode SD1 and a second source/drain electrode SD2. The pair of source/drain electrodes SD1 and SD2 may be spaced apart from each other with the gate electrode therebetween.

The pair of source/drain electrodes SD1 and SD2 may be disposed on the phase change region PLa in the phase change material layer PL. The phase change region PLa may extend above the pair of source/drain electrodes SD1 and SD2 (e.g., above lower surfaces of the pair of source/drain electrodes SD1 and SD2). For example, the pair of source/drain electrodes SD1 and SD2 may be in contact with the phase change region PLa.

The pair of source/drain electrodes SD1 and SD2 may be electrically connected to or insulated from each other by the phase change region PLa. For example, when the phase change region PLa has the 1T′ structure, the pair of source/drain electrodes SD1 and SD2 may be electrically connected to each other by the phase change region PLa. In this case, the phase change region PLa may extend above the pair of source/drain electrodes SD1 and SD2 (e.g., above lower surfaces of the pair of source/drain electrodes SD1 and SD2), and the phase change region PLa may have the 1T′ structure in a region contacting the pair of source/drain electrodes SD1 and SD2. Due to characteristics of the 1T′ structure having high electric conductivity, contact resistance between the pair of source/drain electrodes SD1 and SD2 and the phase change region PLa (i.e., between the pair of source/drain electrodes SD1 and SD2 and the channel region) may reduce. As a result, electrical characteristics of the semiconductor device may be improved. For another example, when the phase change region PLa has the 2H structure, the pair of source/drain electrodes SD1 and SD2 may be electrically insulated from each other by the phase change region PLa.

According to the inventive concept, the accumulation of charges is induced in the channel region (e.g., in the phase change region PLa) by controlling the voltage applied to the gate electrode GE, and the crystal structure of the channel region changes due to the accumulation of charges. The electric conductivity of the channel region changes due to a change in the crystal structure of the channel region, and the changed crystal structure may be maintained even if the voltage is removed from the gate electrode GE. In this manner, the semiconductor device according to the inventive concept may perform both data storage and operation.

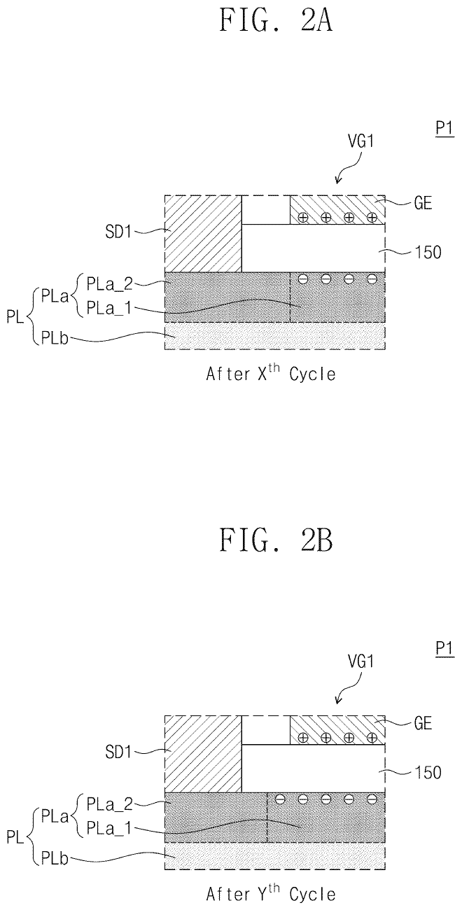

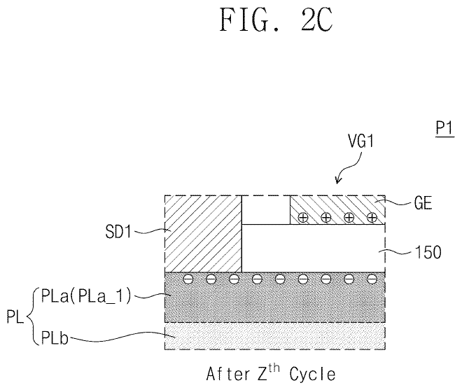

FIGS. 2A to 2C, which correspond to P1 of FIG. 1, are enlarged views illustrating a crystal structure change of a phase change material layer according to a cycle of voltage application to a gate electrode.

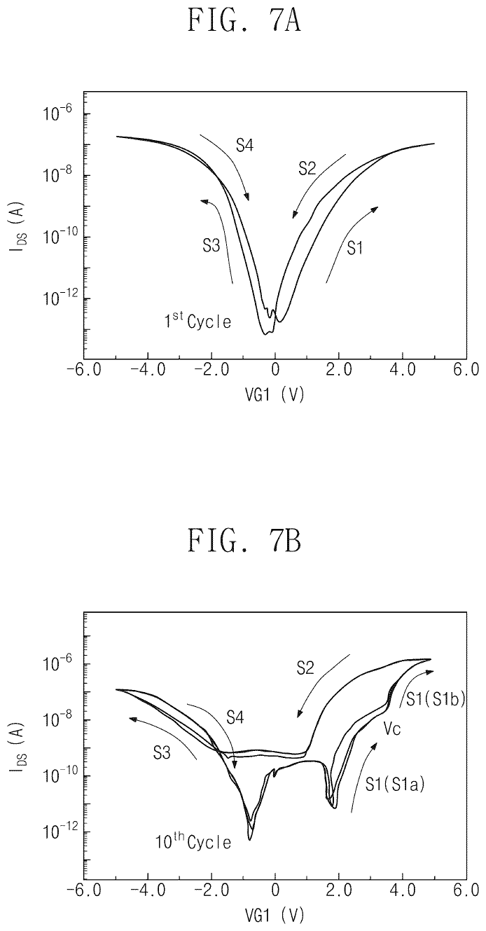

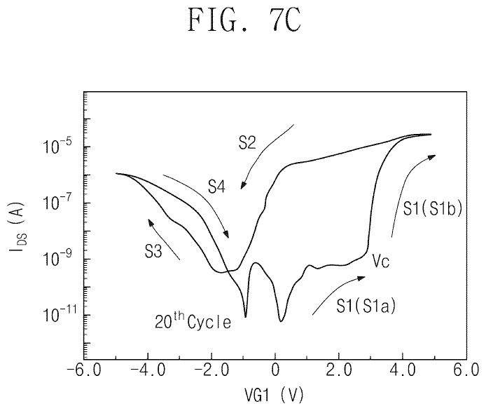

Referring to FIGS. 2A to 2C, charges may be accumulated in the phase change region PLa by repeatedly applying a voltage VG1 to the gate electrode GE. The first voltage VG1 may be controlled to be repeatedly increased and decreased within a certain voltage range, and, in the present disclosure, a minimum repetition interval of voltage value change is defined as one cycle. For example, as illustrated in FIGS. 7A to 7C, the first voltage VG1 may be repeatedly increased and decreased along a first section S1, a second section S2, a third section S3, and a fourth section S4, wherein the first to fourth sections S1 to S4 may constitute one cycle of the first voltage VG1. Here, the accumulated charges may be electrons.

When the first voltage VG1 that is at least a threshold value is applied to the gate electrode GE after the cycle of the first voltage VG1 is repeated, the crystal structure of at least a portion of the phase change region PLa may change due to the accumulation of charges. For example, as the first voltage VG1 that is at least the threshold value is applied to the gate electrode GE after the cycle of the first voltage VG1 is repeated, the crystal structure of at least a portion of the phase change region PLa may change from the 2H structure to the 1T′ structure. Here, one region of the phase change region PLa changed to the 1T′ structure may be defined as a first region PLa_1, and a remaining region of the phase change region PLa maintaining the 2H structure may be defined as a second region PLa_2. As the application of the first voltage VG1 is repeated, a range of the first region PLa_1 may extend.

In more detail, referring to FIG. 2A, when the first voltage VG1 that is at least the threshold value is applied to the gate electrode GE after X cycles of application of the first voltage VG1 to the gate electrode GE, the first region PLa_1 having the 1T′ structure and the second region PLa_2 having the 2H structure may be provided. The first source/drain electrode SD1 may be spaced apart from the first region PLa_1, and may be provided on the second region PLa_2. For example, the first region PLa_1 may vertically overlap the gate electrode GE.

Referring to FIG. 2B, when the first voltage VG1 that is at least the threshold value is applied to the gate electrode GE after Y cycles of application of the first voltage VG1 to the gate electrode GE (Y>X), the first region PLa_1 having the 1T′ structure and the second region PLa_2 having the 2H structure may be provided. Here, compared to FIG. 2A, the first region PLa_1 may be closer to the first source/drain electrode SD1. In other words, as the cycle of the first voltage VG1 is repeated, the first region PLa_1 may further extend to a region adjacent to the first source/drain electrode SD1. Therefore, the second region PLa_2 may further reduce.

Referring to FIG. 2C, when the first voltage VG1 that is at least the threshold value is applied to the gate electrode GE after Z cycles of application of the first voltage VG1 to the gate electrode GE (Z>Y), the first region PLa_1 may occupy an entirety of the phase change region PLa. In other words, the crystal structure of the entirety of the phase change region PLa may be the 1T′ structure. Therefore, the first source/drain electrode SD1 may be disposed on the first region PLa_1 (i.e., the phase change region PLa having the 1T′ structure). As a result, through repeated application of the first voltage VG1, the phase change region PLa having the 1T′ structure may be electrically connected to the first source/drain electrode SD1, and the contact resistance between the phase change region PLa and the first source/drain electrode SD1 may be improved.

Hereinafter, an operation of performing a plurality of cycles of application of the first voltage VG1 so as to extend the first region PLa_1, in which phase change occurs, in the phase change region PLa, as illustrated in FIGS. 2A to 2C, is referred to as a forming process.

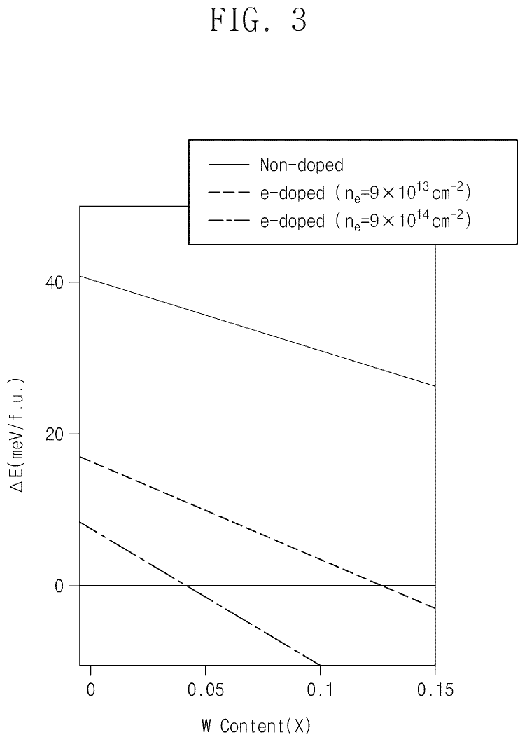

FIG. 3 is a graph illustrating lattice structure energy according to W content in Mo₁₋ₓWₓTe₂ for each crystal structure and electron density.

Referring to FIG. 3, a value obtained by subtracting lattice structure energy of the Mo₁₋ₓWₓTe₂ having the 2H structure from lattice structure energy of the Mo₁₋ₓWₓTe₂ having the 1T′ structure is illustrated in the graph for each electron density. Herein, the lattice structure energy may be defined as energy per unit that atoms have in order to form a crystal structure. The lattice structure energy according to the W content for each crystal structure was calculated through a first-principles density functional theory on the basis of a temperature of 0 K.

When electrons are not doped, the lattice structure energy of the 1T′ structure is higher than the lattice structure energy of the 2H structure in a section in which x ranges from about 0 to about 0.15. In other words, the 1T′ structure with non-doped electrons has a more unstable state than the 2H structure when x is about 0 to about 0.15.

When doped with electron density nₑ=9×10¹³ cm⁻², the lattice structure energy of the 1T′ structure is higher than the lattice structure energy of the 2H structure in a section in which x ranges from about 0 to about 0.13 and lower than the lattice structure energy of the 2H structure in a section in which x is larger than about 0.13. In other words, the 1T′ structure doped with the electron density nₑ=9×10¹³ cm⁻² has a more unstable state than the 2H structure when x is about 0 to about 0.13 and has a more stable state than the 2H structure when x is larger than about 0.13.

When doped with electron density nₑ=2×10¹⁴ cm⁻², the lattice structure energy of the 1T′ structure is higher than the lattice structure energy of the 2H structure in a section in which x ranges from about 0 to about 0.04 and lower than the lattice structure energy of the 2H structure in a section in which x is larger than about 0.04. In other words, the 1T′ structure doped with the electron density nₑ=2×10¹⁴ cm⁻² has a more unstable state than the 2H structure when x is about 0 to about 0.04 and has a more stable state than the 2H structure when x is larger than about 0.04.

As a result, a stable state of Mo₁₋ₓWₓTe₂ may be achieved by adjusting the electron density and W content.

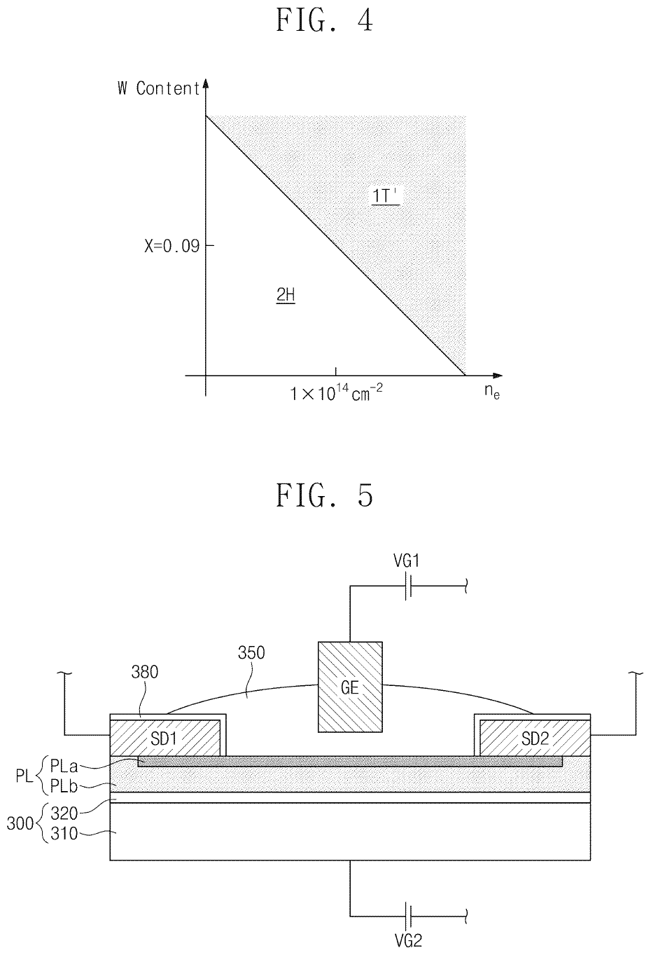

FIG. 4 is a graph illustrating a crystal structure according to electron density and W content in Mo₁₋ₓWₓTe₂.

Referring to FIG. 4, the Mo^{1-x}WₓTe₂ may have the 1T′ structure at a lower temperature as an x value increases. For example, when x=0.09, the Mo₁₋ₓWₓTe₂ may have the 2H structure or 1T′ structure with respect to electron density nₑ=1×10¹⁴ cm⁻².

FIG. 5 is a diagram schematically illustrating a semiconductor device according to Experimental Example 1. Hereinafter, the semiconductor device according to the inventive concept and characteristics thereof will be described in more detail through Experimental Example 1 that implements an embodiment of the inventive concept.

### Experimental Example 1

Referring to FIG. 5, a substrate 300 including a semiconductor substrate 310 and a dielectric substrate 320 on the semiconductor substrate 310 is prepared. The semiconductor substrate 310 is a silicon substrate, and the dielectric substrate 320 is a silicon oxide substrate. The phase change material layer PL including the phase change region PLa and the base region PLb is formed on the substrate 300. In the phase change material layer PL, Mo_{0.91}W_{0.09}Te₂ is provided in a plurality of layers. The gate electrode GE and the pair of source/drain electrodes SD1 and SD2 are disposed on the phase change material layer PL. The gate electrode GE and the pair of source/drain electrodes SD1 and SD2 are configured as a multi-layer structure of chromium and gold. Ion-gel 350 is formed between the gate electrode GE and the phase change material layer PL. The ion-gel 350 includes N, N-diethyl-N-(2-methoxyethyl)-N-methylammonium bis-(trifluoromethyl sulfonyl)-imide (DEMETFSI). A passivation film 380 covers the pair of source/drain electrodes SD1 and SD2, and the pair of source/drain electrodes SD1 and SD2 are spaced apart from the ion-gel 350. The passivation film 380 is formed of polymethyl methacrylate (PMMC).

The first voltage VG1 is applied to the gate electrode GE in order to induce accumulation of charges in the phase change material layer PL. Accumulation of charges is also induced under the phase change material layer PL by applying a second voltage VG2 to the semiconductor substrate 310.

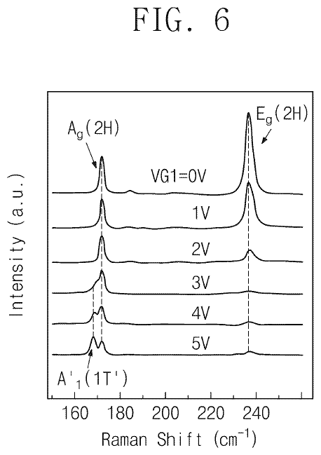

FIG. 6 is a graph illustrating Raman spectra in a phase change material layer according to a voltage applied to the gate electrode in Experimental Example 1.

FIG. 6 shows Raman spectra of the phase change material layer PL when the first voltage VG1 is applied as 0 V to 5 V after a forming process is completed. When the first voltage VG1 is applied as 0 V to 2 V, a shift value corresponding to the 2H structure is identified, but a shift value corresponding to the 1T′ structure is not identified. When the first voltage VG1 is applied as 3 V to 5 V, shift values corresponding to the 2H structure and 1T′ structure are identified. In this manner, it is confirmed that at least a portion of the phase change material layer PL (e.g., the first region PLa_1 of the phase change region PLa) changes from the 2H structure to the 1T′ structure according to a voltage applied to the gate electrode GE after the forming process is completed.

FIGS. 7A to 7C are graphs illustrating a hysteresis loop of a current according to a cycle of voltage application to the gate electrode of Experimental Example 1.

Referring to FIGS. 7A to 7C, it may be confirmed that a hysteresis loop of current between the pair of source/drain electrodes SD1 and SD2 and the phase change material layer PL varies according to a cycle count of the first voltage VG1. Here, a measured current value is a value of current generated by applying a voltage between the pair of source/drain electrodes SD1 and SD2, and a constant voltage is applied to the pair of source/drain electrodes SD1 and SD2 regardless of a change in the first voltage VG1. The first voltage VG1 is repeatedly increased and decreased along a first section S1, a second section S2, a third section S3, and a fourth section S4, wherein the first to fourth sections S1 to S4 constitute one cycle of the first voltage VG1. In the first section S1, an absolute value of the first voltage VG1 increases from 0 V to a positive voltage. In the second section S2, the absolute value of the first voltage VG1 decreases from a positive voltage to 0 V. In the third section S3, the absolute value of the first voltage VG1 increases from 0 V to a negative voltage. In the fourth section S4, the absolute value of the first voltage VG1 decrease from a negative voltage to 0 V.

Referring to FIG. 7A, when a first cycle of the first voltage VG1 is in progress, the current increases as the absolute value of the first voltage VG1 increases (S1, S3), and the current decreases as the absolute value of the first voltage VG1 decreases (S2, S4). Current values for the same first voltage VG1 are similar in the first and second sections S1 and S2, and current values for the same first voltage VG1 are similar in the third and fourth sections S3 and S4. This is because when the first cycle is in progress (i.e., when the forming process is not in progress), accumulation of charges is induced and the current increases as the first voltage VG1 increases, but there is no change in electric conductivity due to a phase change.

Referring to FIG. 7B, when a 10th cycle of the first voltage VG1 is in progress, the current values for the same first voltage VG1 are different in the first and second sections S1 and S2. This is because the crystal structure of a portion of the phase change region PLa changes from the 2H structure to the 1T′ structure in the first section S1, and thereafter the 1T′ structure is maintained even if a voltage value decreases in the second section S2. The phase change region PLa includes the 1T′ structure even if the voltage value finally decreases to 0 V. Therefore, the current value is higher in the second section S2 than in the first section S1 even if the same value of the first voltage VG1 is provided.

Here, the first section S1 may be divided into A section S1a and B section S1b before and after a threshold voltage Vc. The threshold voltage Vc is defined as a voltage value at a moment at which the current value sharply increases as the first voltage VG1 increases within the first section S1. The phase change region PLa has the 2H structure in the A section Sla of a lower voltage than the threshold voltage Vc, and gradually changes to the 1T′ structure as the voltage gradually increases in the B section S1b. Therefore, not only the accumulation of charges but also an increase in electric conductivity due to a phase change is reflected in the B section S1b, and, as a result, a current increases relatively sharply in the B section S1b in comparison with the A section Sla.

Thereafter, in the third and fourth sections S3 and S4, the electron density in the phase change region PLa reduces, and thus the 1T′ structure of the phase change region PLa changes back to 2H structure. Here, unlike the case where the crystal structure of the phase change region PLa changes from the 2H structure to the 1T′ structure due to the accumulation of charges in the section S1, the phase change region PLa of the 2H structure does not change to the 1T′ structure even if holes are accumulated since a negative voltage is applied. Therefore, the current values for the same first voltage VG1 are similar in the third and fourth sections S3 and S4.

Referring to FIG. 7C, when a 20th cycle of the first voltage VG1 is in progress, the current values for the same first voltage VG1 are different in the first and second sections S1 and S2 as in FIG. 7B. However, a difference of current increase rate according to the first voltage VG1 between the A section Sla and the B section S1b is more significant in comparison with FIG. 7B. Furthermore, although the first voltage VG1 is 0 V in the second section S2, the current value is maintained as about 10⁻⁶ A similar to that of typical metal. This is because a larger number of cycles are performed (i.e., forming process is executed) in comparison with FIG. 7B so that phase change to the 1T′ structure is performed in a wider region in the phase change region PLa. Therefore, when comparing the B section S1b of FIG. 7C with the B section S1b of FIG. 7B, the current value is larger at the same value of the first voltage VG1 in FIG. 7C. Furthermore, even when the first voltage VG1 is 0 V in the second section S2, the current value is large due to electric conductivity of the 1T′ structure. As the cycle is further repeated, the contact resistance between the phase change region PLa and the first source/drain electrode SD1 decreases since the first region PLa_1 extends, and thus the current value may increase.

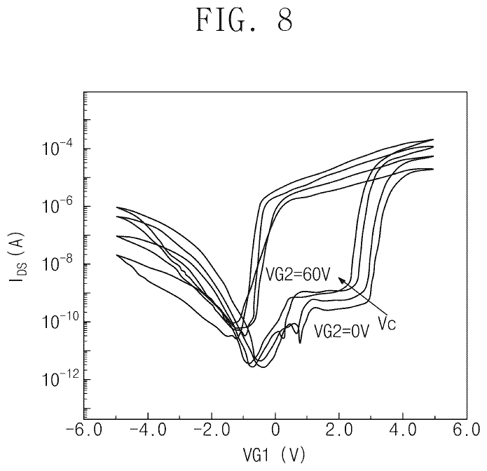

FIG. 8 is a graph illustrating hysteresis loops of current according to the first and second voltages of Experimental Example 1.

Referring to FIG. 8, after the forming process is completed, hysteresis loops of current according to the first and second voltages VG1 and VG2 are shown. The second voltage VG2 is a sort of back gate voltage applied to the semiconductor substrate 310. The threshold voltage Vc of the first voltage VG1 tends to decrease as the second voltage VG2 increases from 0 V to 60 V. By using this phenomenon, a value of the threshold voltage Vc at which phase change occurs may be adjusted to a desired degree by adjusting a value of the second voltage VG2.

According to the inventive concept, the accumulation of charges is induced in the channel region by controlling the voltage applied to the gate electrode in the semiconductor device, and the crystal structure of the channel region changes due to the accumulation of charges. The electric conductivity of the channel region changes due to a change in the crystal structure of the channel region, and the changed crystal structure may be maintained even if the voltage is not applied in the gate electrode. In this manner, the semiconductor device according to the inventive concept may perform both data storage and operation.

Furthermore, the electrical characteristics of the semiconductor device may be improved by improving the contact resistance between the channel region and the source drain electrodes.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A semiconductor device comprising:
a phase change material layer on a substrate;
a gate electrode disposed on the phase change material layer and inducing accumulation of charges in the phase change material layer; and
a pair of source/drain electrodes spaced apart from each other with the gate electrode therebetween on the phase change material layer,
wherein the phase change material layer includes a phase change region having a crystal structure that changes due to the accumulation of the charges as a voltage is applied to the gate electrode.

2. The semiconductor device of claim 1, wherein the phase change material layer includes Mo₁₋ₓWₓTe₂.

3. The semiconductor device of claim 2, wherein x is 0.05 to 0.15 in the Mo₁₋ₓWₓTe₂.

4. The semiconductor device of claim 1,
wherein the phase change material layer is provided as a plurality of layers stacked on the substrate, and
the phase change region includes an uppermost layer among the plurality of layers.

5. The semiconductor device of claim 1, wherein the charges are electrons.

6. The semiconductor device of claim 1, wherein a thickness of the phase change material layer is about 2 nm or less.

7. The semiconductor device of claim 1, wherein the gate electrode is disposed on the phase change region.

8. The semiconductor device of claim 1, wherein the phase change region extends above the pair of source/drain electrodes.

9. The semiconductor device of claim 1, wherein a width of the phase change region is larger than a width of the gate electrode.

10. The semiconductor device of claim 1, wherein the phase change region changes from a hexagonal structure to a monoclinic structure as the voltage is applied to the gate electrode.

11. The semiconductor device of claim 10, wherein the phase change region maintains the monoclinic structure even when the voltage is removed from the gate electrode.

12. The semiconductor device of claim 1, wherein the phase change region has a monoclinic structure, and the pair of source/drain electrodes are electrically connected to each other by the phase change region.

13. The semiconductor device of claim 1,
wherein the pair of source/drain electrodes contact the phase change region, and
the phase change region has a monoclinic structure in a region that contacts the pair of source/drain electrodes.

14. The semiconductor device of claim 1, wherein the phase change region has a hexagonal structure, and the pair of source/drain electrodes are electrically insulated from each other.

15. A semiconductor device comprising:
a phase change material layer on a substrate;
a gate electrode disposed on the phase change material layer; and
a pair of source/drain electrodes spaced apart from each other with the gate electrode therebetween on the phase change material layer,
wherein the phase change material layer includes a phase change region having a monoclinic structure and a base region having a hexagonal structure.

16. The semiconductor device of claim 15, wherein the phase change material layer includes Mo₁₋ₓWₓTe₂.

17. The semiconductor device of claim 16, wherein x is 0.05 to 0.15 in the Mo₁₋ₓWₓTe₂.

18. The semiconductor device of claim 15, wherein the pair of source/drain electrodes are disposed on the phase change region.

19. The semiconductor device of claim 15, wherein the phase change region is disposed between the gate electrode and the base region.

20. The semiconductor device of claim 15, wherein a width of the phase change region is larger than a width of the gate electrode.
